(19) United States
(12) Patent Application Publication
(10) Pub. No.: US 2016/0284523 A1
(43) Pub. Date: Sep. 29, 2016

(54) Hydrofluoroolefin Etching Gas Mixtures

(71) Applicant: The Chemours Company FC, LLC, Wilmington, DE (US)

(72) Inventors: GARY LOH, NEWARK, DE (US); MARIO JOSEPH NAPPA, NEWARK, DE (US); HAO-CHUN LEE, HSINCHU (TW); TAI-CHEN LEE, TAOYUAN CITY (TW)

(21) Appl. No.: 14/777,865

(22) PCT Filed: Mar. 28, 2014
(86) PCT No.: PCT/US14/32111

§ 371 Date: Sep. 17, 2015

Related U.S. Application Data
(60) Provisional application No. 61/806,140, filed on Mar. 28, 2013.

(51) Int. Cl. H01J 37/32; C11D 7/30; C09K 13/00; C23C 16/44

(52) U.S. Cl. CPC H01J 37/32862; C23C 16/4405; H01J 37/32357; C11D 7/30; C09K 13/00; H01J 2237/334

(57) ABSTRACT

The present invention relates to hydrofluorolefin compositions useful for removing surface deposits in CVD chambers, and relates to methods for removing surface deposits from the interior of a chemical vapor deposition chamber by using an activated gas mixture created by activating a gas mixture in the chamber or in a remote chamber, where the gas mixture comprises a hydrofluorolefin.

### FIELD OF THE INVENTION

The present invention relates to hydrofluorolefin compositions useful as etching and cleaning gases for removing surface deposits in CVD and PECVD chambers. The invention further relates to methods for removing surface deposits from the interior of a chemical vapor deposition chamber by using an activated gas mixture created by activating a gas mixture in the chamber or in a remote chamber, where the gas mixture includes a hydrofluorolefin and, preferably, oxygen.

### BACKGROUND OF THE INVENTION

Etching gases used in the semiconductor industry are used to etch deposits from a surface. Chemical vapor deposition (CVD) and plasma enhanced chemical vapor deposition (PECVD) chambers need to be regularly cleaned to remove deposits from the chamber walls and platens. This cleaning process reduces the productive capacity of the chamber since the chamber is out of active service during a cleaning cycle. The cleaning process may include, for example, the evacuation of reactant gases and their replacement with a cleaning gas, activation of that gas, followed by a flushing step to remove the cleaning gas from the chamber using an inert carrier gas. The cleaning gases typically work by etching the contaminant build-up from the interior surfaces, thus the etching rate of the cleaning gas is an important parameter in the utility and commercial use of the gases, and some cleaning gases can also be used as etching gases. In addition, present cleaning gases have significant amounts of components with high global warming potentials. For example, U.S. Pat. No. 6,449,521 discloses a mixture of 54% oxygen, 40% perfluoroethane and 6% NF₃ as a cleaning gas for CVD chambers. However, perfluorethane has a relatively high GWP, estimated to be on the order of 6200 at a time horizon of 20 years, and 14000 at a time horizon of 500 years. Other cleaning gases include C3F8, which also has a significant global warming potential. Moreover, even when processes are optimized, there is the potential for release of the cleaning gases. Finally, given the chemical stability of these gases, their activation can be energy intensive

It is further understood that that these gases may generate relatively high amounts of toxic waste gases, which may pose additional GWP or Environmental, Health, and Safety (EHS) issues apart from the GWP of the cleaning or etch gas itself. Thus, there is a need in the art to reduce the harm of global warming caused by the cleaning and operation of CVD reactors with an effective and inexpensive cleaning/etching gas that has a high etch rate and a lower GWP and ESH impact than incumbent gases.

### BRIEF SUMMARY OF THE INVENTION

The present invention provides a clean gas mixture that have low EHS and GWP, so that even if unreacted gases are released, they have reduced environmental impact. The invention also provides methods of using these gases, comprising activating the gas, either in a remote chamber or in situ in the process chamber, wherein the gas mixture comprises an oxygen source and a hydrofluoroolefin, and contacting the activated gas with the surface deposits for a time sufficient to remove said deposits. The gas mixtures can be activated by an RF source using sufficient power for a sufficient time such that said gas mixture reaches a neutral temperature of about 1000-3,000 K to form an activated gas mixture or alternatively using a glow discharge to activate the gas, and thereafter contacting said activated gas mixture with the surface deposits and thereby removing at least some of said surface deposits. The gas mixtures comprise a hydrofluorolefin having up to four carbons (C4) with the percent fluorine equal to or higher than 65%. The gas mixture may also have a ration of H to F ratio equal to or less than 60%.

### DETAILED DESCRIPTION OF THE INVENTION

Surface deposits removed with this invention include those materials commonly deposited by chemical vapor deposition (CVD) or plasma-enhanced chemical vapor deposition (PECVD) or similar processes. Such materials include nitrogen-containing deposits such as, without limitation, silicon nitride, silicon oxynitride, silicon carbonitride (SiCN), silicon boronitride (SiBN), and metal nitrides, such as tungsten nitride, titanium nitride or tantalum nitride. In one embodiment of the invention, a preferred surface deposit is silicon nitride.

In one embodiment of the invention surface deposits are removed from the interior of a process chamber that is used in fabricating electronic devices. Such a process chamber could be a CVD chamber or a PECVD chamber. Other embodiments of the invention include, but are not limited to, removing surface deposits from metals, the cleaning of plasma etching chambers and removal of N-containing thin films from a wafer. In one embodiment of the gas is used in an etching application.

In one embodiment, the process of the present invention involves an activating step wherein a cleaning gas mixture is activated in a remote chamber. Activation may be accomplished by any means allowing for the achievement of dissociation of a large fraction of the feed gas, such as: radio frequency (RF) energy, direct current (DC) energy, laser illumination, and microwave energy. One embodiment of this invention is using transformer coupled inductively coupled lower frequency RF power sources in which the plasma has a torroidal configuration and acts as the secondary of the transformer. The use of lower frequency RF power allows the use of magnetic cores that enhance the inductive coupling with respect to capacitive coupling; thereby allowing the more efficient transfer of energy to the plasma without excessive ion bombardment which limits the lifetime of the remote plasma source chamber interior. Typical RF power used in this invention has a frequency lower than 1000 kHz. In another embodiment of this invention the power source is a remote microwave, inductively, or capacitively coupled plasma source. In yet another embodiment of the invention, the gas is activated using a glow discharge.

Activation of the cleaning gas mixture uses sufficient power for a sufficient time to form an activated gas mixture. In one embodiment of the invention the activated gas mixture has a neutral temperature on the order of at least about 1000-3,000 K. The neutral temperature of the resulting plasma depends on the power and the residence time of the gas mixture in the remote chamber. Under certain power input and conditions, neutral temperature will be higher with longer residence times. In one embodiment of the invention, a preferred neutral temperature of the activated gas mixture is over about 3,000 K. Under appropriate conditions (considering power, gas composition, gas pressure and gas residence time), neutral temperatures of at least about 1000-5,000 K may be achieved.

Table 1 depicts hydrofluorolefins (HFOs) that have use in etch gas applications. Preferred HFOs have up to four carbons (C4) with the percent fluorine equal to or higher than 65% (F%>65%). Preferably, the HFOs have an H to F ratio equal to or less than 60%. Preferably, the HFOs may be blended with oxygen is a HFO/O2 ration of 0.1-3:1.0-0.1 or existing etch/cleaning gases, or both. Preferably, the blend is further mixed with a carrier gas, such as argon, helium or nitrogen.

TABLE 1

| | | | % | H/F | F/C | B.p |
|---|---|---|---|---|---|---|
| HFO (TO C4) with F % >65% & HF ratio <60% | | MW | F | ratio | ratio | (C) |
| HFO-1123 | CHF═CF2 | 82.0 | 69% | 33.3% | 1.7 | −51 |
| Z—HFO-1225ye | Z—CF3—CF═CHF | 132.0 | 72% | 20.0% | 1.7 | −19 |
| Z—HFO1225ye | Z—CF3—CF═CHF | 132.0 | 72% | 20.0% | 1.7 | −14 |
| HFO-1225zc | CF3—CH═CF2 | 132.0 | 72% | 20.0% | 1.3 | −22 |
| HFO_1234YF | CF3—CF═CH2 | 114.0 | 67% | 50.0% | 1.3 | −29 |
| HFO—E-F1234ZE | CF3—CH═CHF | 114.0 | 67% | 50.0% | 1.3 | −19 |
| HFO—Z-F1234ze | CF2═CH—CHF | 114.0 | 67% | 50.0% | 2.0 | 9 |
| HFO-1216 | CF2═CF—CF3 | 150.0 | 76% | 50.0% | 1.5 | −30 |
| HFO—Z-1336mzz | CF3CH═CH—CF3 (Z isomer) | 164.0 | 70% | 33.3% | 1.5 | 33 |
| HFO—E-1336mzz | CF3—CH═CHCF3 (E-isomer) | 164.0 | 70% | 33.3% | 1.5 | 7.5 |
| HFO—Z-1336ze | CF3—CF2—CH═CHF (Z isomer) | 164.0 | 70% | 33.3% | 1.5 | 31 |
| HFO—E-1336ze | CF3—CF2—CH═CHF (E isomer) | 164.0 | 70% | 33.3% | 1.5 | 11 |
| HFO-1336yf | CH2═CF—CF2—CF3 | 164.0 | 70% | 33.3% | 1.5 | 5 |
| HFO-1336pyy | CHF2—CF═CF—CHF2 | 164.0 | 70% | 33.3% | 2.0 | ~61 |
| Z—PFC-1318my | CF3—CF═CF—CF3 (Z isomer) | 200.0 | 76% | 0.0% | 2.0 | 0 |
| E—PFC-1318my | CF3—CF═CF—CF3 (E isomer) | 200.0 | 76% | 0.0% | 1.8 | 0 |
| E—HFOC-1327myz | CF3—CF═CH—CF3 (E isomer) | 182.0 | 73% | 14.3% | 1.8 | ~10 |
| F—HFOC-1327myz | CF3—CF═CH—CF3 (Z isomer) | 182.0 | 73% | 14.3% | 1.8 | ~10 |
| E—HFO-1327ye | CHF═CF—CF2—CF3 (E isomer) | 182.0 | 73% | 14.3% | 1.8 | 10 |
| Z—HFO-1327ye | CHF═CF—CF2—CF3 (Z isomer) | 182.0 | 73% | 14.3% | 1.8 | 10 |
| HFO-1327cze | CF2═CF—CHF—CF3 | 182.0 | 73% | 14.3% | 1.8 | ~16 |
| HFO-1327et | CHF═C(CF3)2 | 182.0 | 73% | 14.3% | 1.8 | 18-24 |
| HFO-1327 | CF2═C(CF3)(CHF2) | 182.0 | 73% | 14.3% | 1.3 | 18-24 |
| HFO-1345czf | CF2═CH—CH2—CF3 | 146.1 | 65% | 60% | 1.3 | ~8 |
| HFO-1345fyc | CH2═CF—CF2—CHF2 | 146.1 | 65% | 60% | 1.3 | ~18 |
| HFO-1345cye | CF2═CF—CHF—CH2F | 146.1 | 65% | 60% | 1.3 | ~52 |
| HFO-1345cyf | CF2═CFCH2CHF2 | 146.1 | 65% | 60% | 1.3 | ~44 |
| HFO-1345eye | CHF═CF—CHF—CHF2 | 146.1 | 65% | 60% | 1.3 | ~52 |
| HFO-1345pyz | CHF2—CF═CH—CHF2 | 146.1 | 65% | 60% | 1.3 | ~55 |
| E—HFO-1345pyy | CHF2—CF═CF—CH2F | 146.1 | 65% | 60% | 1.3 | ~74 |
| Z—HFO-1345pyy | CHF2—CF═CF—CH2F | 146.1 | 65% | 60% | 1.3 | ~74 |
| E—HFO-1345zy | CHF2—CH═CF—CHF2 (E isomer) | 146.1 | 65% | 60% | 1.3 | ~55 |
| Z—HFO-1345zy | CHF2—CH═CF—CHF2 (Z isomer) | 146.1 | 65% | 60% | 1.5 | ~55 |
| PFBY2 | CF3C═CCF3 | 162.0 | 70% | 0% | 1.5 | −24 |
| HFO-1233zd | CHCl═CH—CF3 | 130 | 67% | 50% | 1.3 | 19 |

Hydrochlorofluoroolefins, such as HFO-1233zd, 1-chloro-3,3,3-trifluoropropene, may also be used as a hydrofluoroolefin.

The activated gas may be formed in a separate, remote chamber that is outside of the process chamber, but in close proximity to the process chamber. In this invention, remote chamber refers to the chamber other than the cleaning or process chamber, wherein the activated gas plasma may be generated, and process chamber refers to the chamber wherein the surface deposits are located. The remote chamber is connected to the process chamber by a conduit or other means allowing for transfer of the activated gas from the remote chamber to the process chamber. For example, the transport passage may comprise a short connecting tube and a showerhead of the CVD/PECVD process chamber. The remote chamber and means for connecting the remote chamber with the process chamber are constructed of materials known in this field to be capable of containing activated gas mixtures. For instance, ceramics, aluminum and anodized aluminum are commonly used for the chamber components. Sometimes Al₂O₃ is coated on the interior surface to reduce the surface recombination. In other embodiments of the invention, the activated gas mixture may be formed directly in the process chamber.

The gas mixture that is activated to form the activated gas comprises a hydrofluoroolefin. It may further comprise an oxygen source, a nitrogen source or an inorganic fluorine source. Typical inorganic fluorine sources include NF₃ and SF₆. A hydrofluoroolefin of the invention is herein referred to as a compound comprising of C, H and F and having at least unsaturation site, i.e. a carbon-carbon double bond or triple bond. In one embodiment of the invention, the gas mixture further comprises a perfluorocarbon or hydrofluorocarbon. A perfluorocarbon compound as referred to in this invention is a compound consisting of C, F and optionally oxygen. A hydrofluorocarbon compound as referred to in this invention is a compound consisting of C, F, H, and optionally oxygen. Perfluorocarbon compounds include, but are not limited to tetrafluoromethane, hexafluoroethane, octafluoropropane, hexafluororcyclopropane, decafluorobutane, octafluorocyclobutane hexafluoropropene, hexafluoropropylene oxide, hydrofluoroacetone, 2,3,3-trifluor-3-(trifluoromethyl) oxirane, 1,1,1,3,3,3-hexafluoro-2-propanone, octofluoro-2-butene, hexafluoro-1,3-dibutene, C5F8, C4F10, and octafluorotetrahydrofuran, Hydrofluorocarbons include CHF3, CH2F2, HFC-134a, HFC-125, and HFC-152a. Hydrochlorofluoroolefins, such as HFO-1233zd, 1-chloro-3,3,3-trifluoropropene, may also be used as a hydrofluoroolefin. Blends of any of the foregoing may also be mixed with the hydrofluorolefins.

Without wishing to be bound by any particular theory, applicant believes that the hydrofluorolefin of the gas mixture serves as a source of atoms at a more preferred ratios of hydrogen to fluorine, and more preferred ratios of fluorine to carbon, in the activated gas mixture. In certain blends to include nitrogen, typical nitrogen sources include molecular nitrogen (N₂) and NF₃. When NF₃ is the inorganic fluorine source, it can also serve as the nitrogen source. Typical oxygen sources include molecular oxygen (O₂). When the fluorocarbon is octafluorotetrahydrofuran or other oxygen containing fluorocarbon, that can also serve as the oxygen source. In one embodiment of the invention, the oxygen: hydrofluorolefin molar ration is at least 0.3:1. In another embodiment of the invention, the oxygen:hydrofluoroolefin molar ratio is at least 0.5:1. In another embodiment, the oxygen to hydrofluorolefin ration is at least 1-3:1. Depending on the hydrofluoroolefin chosen, in other embodiments of the invention the oxygen:hydrofluoroolefin molar ratio may be 1- 4:1.

The gas mixture that is activated to form the activated gas mixture of the invention may further comprise a carrier gas. Examples of suitable carrier gasses include noble gasses such as argon and helium.

In an embodiment of the invention, the temperature in the process chamber during removal of the surface deposits may be from about 50° C. to about 150° C.

The total pressure in the remote chamber during the activating step may be between about 0.5 torr and about 20 torr using the Astron source. The total pressure in the process chamber may be between about 0.5 torr and about 15 torr. With other types of remote plasma sources or in situ plasmas the pressure ranges.

It is found in this invention that the combination of oxygen and a hydrofluoroolefin results in high etching rates of nitride films such as silicon nitride. These increases also provide lower sensitivity of the etch rate to variations in source gas pressure, chamber pressure and temperature.

The following Examples are meant to illustrate the invention and are not meant to be limiting.

### Examples

The remote plasma source is a commercial toroidal-type MKS ASTRON®ex reactive gas generator unit make by MKS Instruments, Andover, Mass., USA. The feed gases (e.g. oxygen, hydrofluoroolefin, and carrier gas) are introduced into the remote plasma source and passed through the toroidal discharge where they were discharged by the 400 kHz radio-frequency power to form an activated gas mixture. The oxygen is manufactured by Airgas with 99.999% purity. The hydrofluorolefin is selected from Table 1. Argon is manufactured by Airgas with a grade of 5.0. Typically, Ar gas is used to ignite the plasmas, after which timed flows for the feed gases were initiated, after Ar flow was halted. The activated gas mixture then is passed through an aluminum water-cooled heat exchanger to reduce the thermal loading of the aluminum process chamber. The surface deposits covered wafer is placed on a temperature controlled mounting in the process chamber. The neutral temperature is measured by Optical Emission Spectroscopy (OES), in which rotovibrational transition bands of diatomic species like C₂ and N₂ are theoretically fitted to yield neutral temperature. The etching rate of surface deposits by the activated gas is measured by interferometry equipment in the process chamber. Any N₂ gas is added a the entrance of the exhaustion pump both to dilute the products to a proper concentration for FTIR measurement and to reduce the hang-up of products in the pump. FTIR was used to measure the concentration of species in the pump exhaust.

### Example 1

This example illustrates the effect of the addition of hydrofluoroolefin HFO-1234yf with oxygen on the silicon nitride etch rate. In this experiment, the feed gas is composed of oxygen and HFO-1234yf. at molar ratios of O2 to HFO of 0.4 to 1, 0.6 to 1, 1 to 1, and 1.2 to 1. Process chamber pressure is 5 torr. Total gas flow rate is from 1500-2000 sccm, with flow rates for the individual gases set proportionally as required for each experiment. The feeding gas is activated by the 400 kHz 5.9-8.7 kW RF power to an effective neutral temperature. The activated gas then enters the process chamber and etches the silicon nitride surface deposits on the mounting with the temperature controlled at 50° C. The etch rate is over 1900 A/min. The same phenomena is observed in all wafer temperatures tested: 50° C., 100° C. and 150° C.

### Example 2

This example illustrates the effect of the addition of hydrofluoroolefin HFO-1336mxx with oxygen on silicon nitride etch rate. In this experiment, the feed gas is composed of oxygen and HFO-1336mxx. at molar ratios of 02 to HFO of 0.4 to 1, 0.6 to 1, 1 to 1, and 1.2 to 1. Process chamber pressure is 5 torr. Total gas flow rate is from 1500-2000 sccm, with flow rates for the individual gases set proportionally as required for each experiment. The feeding gas is activated by the 400 kHz 5.9-8.7 kW RF power to an effective neutral temperature. The activated gas then enters the process chamber and etches the silicon nitride surface deposits on the mounting with the temperature controlled at 50° C. The etch rate is over 2050 A/min. The same phenomena is observed in all wafer temperatures tested: 50° C., 100° C. and 150° C.

### Example 3

This example illustrates the effect of the addition of a high-fluorine blend comprising hydrofluoroolefin HFO-1336mxx and CF4, with oxygen on silicon nitride etch rate. In this experiment, the feed gas is composed of oxygen and a 1:1 HFO-1336mxx:CF4 at molar ratios of O2 to high fluorine blend of 0.4 to 1, 0.6 to 1, 1 to 1, and 1.2 to 1. Process chamber pressure is 5 torr. Total gas flow rate is from 1500-2000 sccm, with flow rates for the individual gases set proportionally as required for each experiment. The feeding gas is activated by the 400 kHz 5.9-8.7 kW RF power to an effective neutral temperature. The activated gas then enters the process chamber and etches the silicon nitride surface deposits on the mounting with the temperature controlled at 50° C. The etch rate is over 2100 A/min. The same phenomena is observed in all wafer temperatures tested: 50° C., 100° C. and 150° C.

### Example 4

This example illustrates the effect of the addition of a high-fluroine blend, hydrofluoroolefin HFO-1234yf and NF₃ and with oxygen on silicon nitride etch rate. In this experiment, the feed gas is composed of oxygen and a 1:1 HFO-1234yf:NF_{3,} at molar ratios of O2 to high fluorine blend of 0.4 to 1, 0.6 to 1, 1 to 1, and 1.2 to 1. Process chamber pressure is 5 torr. Total gas flow rate is from 1500-2000 sccm, with flow rates for the individual gases set proportionally as required for each experiment. The feeding gas is activated by the 400 kHz 5.9-8.7 kW RF power to an effective neutral temperature. The activated gas then enters the process chamber and etches the silicon nitride surface deposits on the mounting with the temperature controlled at 50° C. The etch rate is over 2000 A/min. The same phenomena is observed in all wafer temperatures tested: 50° C., 100° C. and 150° C.

### Example 5

This example illustrates the effect of the addition of a high-fluroine blend, hydrofluoroolefin HFO-1234yf and C3F8, and with oxygen on silicon nitride etch rate. In this experiment, the feed gas is composed of oxygen and a 1:1 HFO-1234yf:C2F6, at molar ratios of O2 to high fluorine blend of 0.4 to 1, 0.6 to 1, 1 to 1, and 1.2 to 1. Process chamber pressure is 5 torr. Total gas flow rate is from 1500-2000 sccm, with flow rates for the individual gases set proportionally as required for each experiment. The feeding gas is activated by the 400 kHz 5.9-8.7 kW RF power to an effective neutral temperature. The activated gas then enters the process chamber and etches the silicon nitride surface deposits on the mounting with the temperature controlled at 50° C. The etch rate is over 2000 A/min. The same phenomena is observed in all wafer temperatures tested: 50° C., 100° C. and 150° C.

### Example 6

This example illustrates the effect of the addition of a high-fluroine blend, hydrofluoroolefin HFO-1234yf and SF6, and with oxygen on silicon nitride etch rate. In this experiment, the feed gas is composed of oxygen and a 1:1 HFO-1234yf:SF6, at molar ratios of O2 to high fluorine blend of 0.4 to 1, 0.6 to 1, 1 to 1, and 1.2 to 1. Process chamber pressure is 5 torr. Total gas flow rate is from 1500-2000 sccm, with flow rates for the individual gases set proportionally as required for each experiment. The feeding gas is activated by the 400 kHz 5.9-8.7 kW RF power to an effective neutral temperature. The activated gas then enters the process chamber and etches the silicon nitride surface deposits on the mounting with the temperature controlled at 50° C. The etch rate is over 2000 A/min. The same phenomena is observed in all wafer temperatures tested: 50° C., 100° C. and 150° C.

### Example 7

This example illustrates the effect of the addition of a hydrofluoroolefin HFO-1438 and NF₃ and with oxygen on silicon nitride etch rate. In this experiment, the feed gas is composed of oxygen and a 1:1 HFO-1234yf:NF_{3,} at molar ratios of O2 to high fluorine blend of 0.4 to 1, 0.6 to 1, 1 to 1, and 1.2 to 1. Process chamber pressure is 5 torr. Total gas flow rate is from 1500-2000 sccm, with flow rates for the individual gases set proportionally as required for each experiment. The feeding gas is activated by the 400 kHz 5.9-8.7 kW RF power to an effective neutral temperature. The activated gas then enters the process chamber and etches the silicon nitride surface deposits on the mounting with the temperature controlled at 50° C. The etch rate is over 2000 A/min. The same phenomena is observed in all wafer temperatures tested: 50° C., 100° C. and 150° C.

While specific embodiments of the invention have been shown and described, further modifications and improvements will occur to those skilled in the art. It is desired that it be understood, therefore, that the invention is not limited to the particular form shown and it is intended in the appended claims which follow to cover all modifications which do not depart from the spirit and scope of the invention.

1. An etch gas mixture for cleaning CVD or PECVD chambers, comprising:
a hydrofluorolefin, wherein said hydrofluorolefin is selected from the group consisting of: HFO-1123, HFO-1438, HFO-1225ye, HFO-1225zc, HFO-1234yf, HFO-1234ze, HFO-1216, HFO-1336mzz, HFO-1336ze, HFO-1336yf, HFO-1336pyy, PFC-1318my, HFOC-1327myz, HFO-1327ye, HFO-1327cze, HFO-1327et, HFO-1327, HFO-1345czf, HFO-1345fyc, HFO-1345cye, HFO-1345cyf, HFO-1345eye, HFO-1345pyz, HFO-1345pyy, HFO-1345zy, PFBY2 and HFO-1233zd, and
oxygen.

2. The etch gas mixture of claim 1, further comprising a carrier gas.

3. The etch gas mixture of claim 1, wherein the carrier gas is He, Ar, or N_{2,}

4. The etch gas mixture of claim 1, wherein the etch gas mixture further comprises a second etch gas, wherein the second etch gas is a perfluorocarbon SF6, or NF_{3.}

5. The etch gas mixture of claim 1, wherein the perfluorocarbon is selected from the group consisting of tetrafluoromethane, hexafluoroethane, octafluoropropane, perfluorotetrahydrofuran, hexaflurobutadiene, and octafluorocyclobutane.

6. A method for removing surface deposits from a surface in a process chamber, comprising:
a.) activating a gas mixture comprising oxygen and a hydrofluorolefin wherein the molar percentage of hydrofluroolefin in the said gas mixture is from about 5% to about 99%,
b.) contacting said activated gas mixture with the surface deposits and thereby removing at least some of said deposits
wherein said hydrofluorolefin is selected from the group consisting of:
HFO-1123, HFO-1438, HFO-1225ye, HFO-1225zc, HFO-1234yf, HFO-1234ze, HFO-1216, HFO-1336mzz, HFO-1336ze, HFO-1336yf, HFO-1336pyy, PFC-1318my, HFOC-1327myz, HFO-1327ye, HFO-1327cze, HFO-1327et, HFO-1327, HFO-1345czf, HFO-1345fyc, HFO-1345cye, HFO-1345cyf, HFO-1345eye, HFO-1345pyz, HFO-1345pyy, HFO-1345zy, PFBY2 and HFO-1233zd, and wherein optionally, the step of activation said gas mixture takes place in a remote chamber.

7. The method of claim 6 wherein said process chamber is the interior of a deposition chamber that is used in fabricating electronic devices.

8. The method of claim 6 wherein the hydrofluoroolefin is HFO-1336mzz, HFO-1234yf or HFO-1234ze.

9. The method of claim 6 wherein the said surface deposit is selected from the group consisting of silicon nitride, silicon oxynitride, silicon carbonitride, tungsten nitride, titanium nitride, and tantalum nitride.

10. The method of claim 6, wherein the said surface deposit is silicon nitride.

11. The method of claim 6, wherein the gas mixture further comprises oxygen in molar ratio of oxygen: hydrofluoroolefin that is at least about 1:1.

12. The method of claim 11, wherein the pressure in the process chamber is no more than 30 torr.

13. The method of claim 11, wherein the pressure in the remote chamber is no more than 50 torr.

14. The etch gas mixture of claim 1, wherein said hydrofluorolefin is selected from the group consisting of: HFO-1438, HFO-1234yf and HFO-1336mzz.

15. The etch gas mixture of claim 14, wherein said hydrofluorolefin is selected from the group consisting of: HFO-1234yf and HFO-1336mzz.

16. The method of claim 6, wherein said hydrofluorolefin is selected from the group consisting of: HFO-1438, HFO-1234yf and HFO-1336mzz.

17. The method of claim 16, wherein the hydrofluoroolefin is selected from the group consisting of: HFO-1336mzz and HFO-1234yf.
